(19) United States
(12) Patent Application Publication
(10) Pub. No.: US 2020/0215663 A1
(43) Pub. Date: Jul. 9, 2020

(54) ANTISTATIC POLYURETHANE POLISHING PAD AND COMPOSITION FOR MANUFACTURING THE SAME

(71) Applicant: XIA TAI XIN SEMICONDUCTOR (QING DAO) LTD., Qingdao (CN)

(72) Inventor: KWANG-BOK KIM, Singapore (SG)

(21) Appl. No.: 16/668,407

(22) Filed: Oct. 30, 2019

Related U.S. Application Data
(60) Provisional application No. 62/778,994, filed on Dec. 13, 2018.

(51) Int. Cl. B24B 37/24; H01L 21/02; H01L 21/321; C08L 75/04; C08G 18/76; C08G 18/42

(52) U.S. Cl. CPC B24B 37/24; H01L 21/02013; H01L 21/3212; C08K 2003/0812; C08G 18/7621; C08G 18/7671; C08G 18/425; C08L 75/04

(57) ABSTRACT

The present disclosure provides a polyurethane polishing pad manufactured from a composition. The composition includes 5 to 15 wt % of MBCA, 25 to 45 wt % of isocyanates, 45 to 55 wt % of polyols, and 1 to 5 wt % of conductive additive. The conductive additive comprises at least one of carbon black, carbon fibers, and aluminum particles.

### CROSS-REFERENCE TO RELATED APPLICATION(S)

This application claims the benefit of and priority to U.S. Provisional Patent Application No. 62/778994 filed on Dec. 13, 2018, the contents of which are incorporated by reference herein.

### FIELD

The present disclosure generally relates to a polyurethane polishing pad. More specifically, the present disclosure relates to a polyurethane polishing pad that has conductive materials to allow the pad surface to be conductive and remove the electrostatic charges accumulated on wafer surface.

### BACKGROUND

Chemical mechanical polishing or chemical mechanical planarization (CMP) is accomplished by holding a semiconductor wafer against a rotating polishing surface or rotating the wafer relative to the polishing surface, under controlled conditions of temperature, pressure, and chemical composition. The polishing surface may be a planar pad formed of a soft and porous material, such as a blown polyurethane. During CMP, the polishing surface is wetted with a chemically reactive and abrasive aqueous slurry. The aqueous slurry may be acidic or basic, and typically includes abrasive particles, reactive chemical agents (such as transition metal chelated salts or oxidizers), and adjuvants (such as solvents, buffers, and/or passivating agents). Specifically, chemical etching is performed by the reactive chemical agents in the slurry, whereas mechanical polishing is performed by the abrasive particles in cooperation with the CMP pad.

During a CMP process, especially one that planarizes wafers having metal layers, electrostatic charges tend to accumulate on the wafer surface due to friction between the wafer and the CMP pad. The electrostatic charges are considered production yield detractor, and may cause circuit shortage and/or induce defects. The electrostatic charges concentrating in a particular region on the wafer surface may also cause local irregularity, which may affect the selectivity or uniformity of the planarization process.

Accordingly, there remains a need to provide a CMP apparatus that overcomes the aforementioned problems.

### SUMMARY

In view of above, an object of the present disclosure is to provide a polyurethane polishing pad that has conductive materials to allow the pad surface to be conductive and remove the electrostatic charges accumulated on wafer surface.

To achieve the above object, an implementation of the present disclosure provides a composition for manufacturing a polyurethane polishing pad. The composition includes 5 to 15 weight percent (wt %) of MBCA, 25 to 45 wt % of isocyanates, 45 to 55 wt % of polyols, and 1 to 5 wt % of conductive additive. The conductive additive is selected from a group comprising carbon black, carbon fibers, and aluminum particles.

To achieve the above object, another implementation of the present disclosure provides a polyurethane polishing pad manufactured from a composition. The composition includes 5 to 15 wt % of MBCA, 25 to 45 wt % of isocyanates, 45 to 55 wt % of polyols, and 1 to 5 wt % of conductive additive. The conductive additive is selected from a group comprising carbon black, carbon fibers, and aluminum particles.

To achieve the above object, another implementation of the present disclosure provides a method of manufacturing a polyurethane polishing pad. The method includes actions S201, S202, and S203. In action S201, a composition for manufacturing the polyurethane polishing pad is provided. The composition can be referred to the previous embodiments. The composition includes 5 to 15 wt % of MBCA, 25 to 45 wt % of isocyanates, 45 to 55 wt % of polyols, and 1 to 5 wt % of conductive additive. The conductive additive is selected from a group comprising carbon black, carbon fibers, and aluminum particles. In action S202, the composition is casted into an open mold. In action S203, the composition is heated to cure and produce a polyurethane resin foam.

To achieve the above object, yet another implementation of the present disclosure provides a CMP apparatus for polishing a wafer. The CMP apparatus includes a platen, a retaining ring, and a carrier head. The platen has a polishing pad for polishing the wafer with a slurry. The polishing pad is a polyurethane polishing pad manufactured from a composition including 5 to 15 wt % of MBCA, 25 to 45 wt % of isocyanates, 45 to 55 wt % of polyols, and 1 to 5 wt % of conductive additive. The conductive additive is selected from a group comprising carbon black, carbon fibers, and aluminum particles. The retaining ring is configured to hold the wafer. The carrier head is connected to the retaining ring and configured to rotate the retaining ring.

As described above, the polyurethane polishing pad of the implementations of the present disclosure is manufactured from a composition having urethane prepolymers and conductive additives. The conductive material in the polishing pad allows the pad surface to be conductive and remove the electrostatic charges accumulated on the wafer surface. Therefore, circuit shortage and/or defects of the wafer caused by the electrostatic charges can be reduced.

### BRIEF DESCRIPTION OF THE DRAWINGS

Implementations of the present technology will now be described, by way of example only, with reference to the attached figures.

FIG. 1 is a schematic diagram of a CMP apparatus according to an implementation of the present disclosure.

FIG. 2 is a flow chart of a method for manufacturing a polyurethane polishing pad according to another implementation of the present disclosure.

### DETAILED DESCRIPTION

The present disclosure will now be described more fully hereinafter with reference to the accompanying drawings, in which exemplary implementations of the disclosure are shown. This disclosure may, however, be embodied in many different forms and should not be construed as limited to the exemplary implementations set forth herein. Rather, these exemplary implementations are provided so that this disclosure will be thorough and complete, and will fully convey the scope of the disclosure to those skilled in the art. Like reference numerals refer to like elements throughout.

The terminology used herein is for the purpose of describing particular exemplary implementations only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

It will be understood that the term “and/or” includes any and all combinations of one or more of the associated listed items. It will also be understood that, although the terms first, second, third etc. may be used herein to describe various elements, components, regions, parts and/or sections, these elements, components, regions, parts and/or sections should not be limited by these terms. These terms are only used to distinguish one element, component, region, part or section from another element, component, region, layer or section. Thus, a first element, component, region, part or section discussed below could be termed a second element, component, region, layer or section without departing from the teachings of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

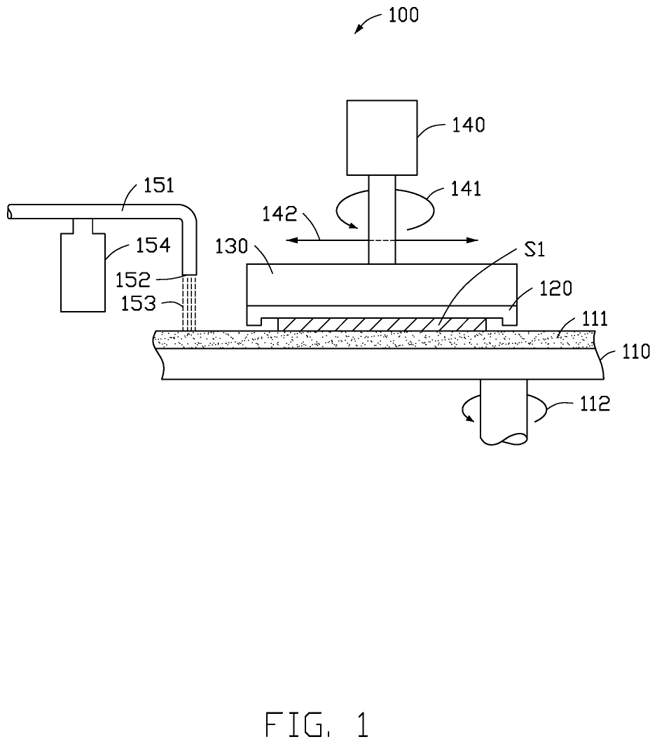

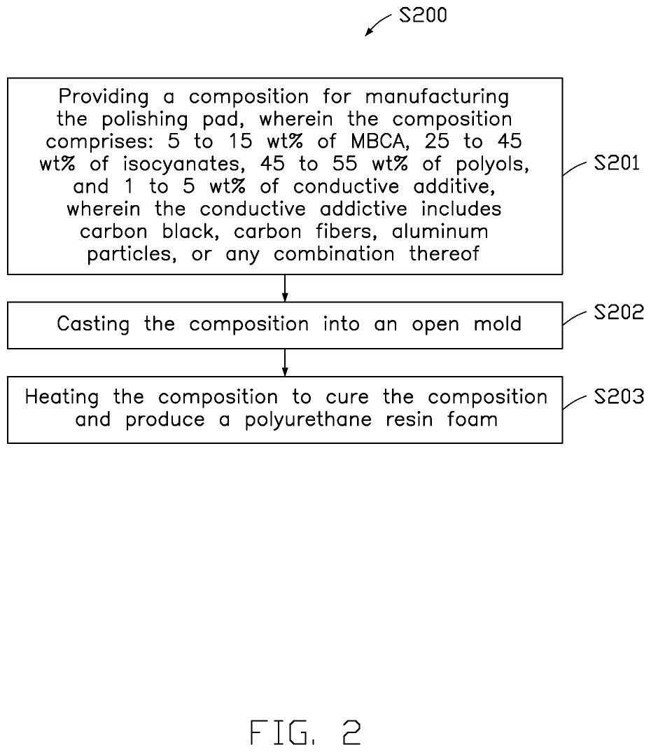

The description will be made as to the exemplary implementations of the present disclosure in conjunction with the accompanying drawings in FIGS. 1 to 2. Reference will be made to the drawing figures to describe the present disclosure in detail, wherein depicted elements are not necessarily shown to scale and wherein like or similar elements are designated by same or similar reference numeral through the several views and same or similar terminology.

The present disclosure will be further described hereafter in combination with the accompanying figures.

Referring to FIG. 1, a schematic diagram of a CMP apparatus is illustrated. The CMP apparatus 100 includes a carrier head 130 and a retaining ring 120. A semiconductor wafer Si is held in the retaining ring 120. A soft pad (not shown in the figure) is positioned between the retaining ring 120 and the wafer S1, with the wafer S1 being held against the soft pad by a partial vacuum or with an adhesive. The carrier head 130 is provided to be continuously rotated by a drive motor 140, in the direction 141, and optionally be reciprocated transversely in the directions 142. Accordingly, the combined rotational and transverse movements of the wafer S1 are intended to reduce the variability in the material removal rate across the surface of the wafer S1. The CMP apparatus 100 further includes a platen 110, which is rotated in the direction 112. A polishing pad 111 is mounted on the platen 110. As compared to the wafer S1, the platen 110 is provided with a relatively large surface area to accommodate the translational movement of the wafer S1 on the retaining ring 120 across the surface of the polishing pad 111. A supply tube 151 is mounted above the platen 110 to deliver a stream of polishing slurry 153, which is dripped onto the surface of the polishing pad 111 from a nozzle 152 of the supply tube 151. The slurry 153 may be gravity fed from a tank or reservoir (not shown), or otherwise pumped through the supply tube 151. Alternatively, the slurry 153 may be supplied from below the platen 110 such that it flows upwardly through the underside of the polishing pad 111. In another embodiment, the slurry may be supplied in the retaining ring 120 by nozzles disposed in the retaining ring 120. If the particles in the slurry 153 forms agglomeration of undesirable large particles, the wafer surface would be scratched when the wafer S1 is being polished. Therefore, the slurry 153 need to be filtered to remove the undesirable large particles. Usually, a filter assembly 154 is coupled to the supply tube 151 to separate agglomerated or oversized particles.

In an embodiment, the polishing pad 111 is an antistatic polishing pad. The antistatic polishing pad of the present implementation is a polyurethane polishing pad including a conductive material. The conductive material allows the pad surface to be conductive and remove the electrostatic charges accumulated on the wafer surface.

The polyurethane polishing pad is manufactured from a composition that includes a plurality of urethane prepolymers and a curative (or hardener) that cross-links the urethane prepolymers. The urethane prepolymers are formed by reacting polyols (e.g., polyether and/or polyester polyols) with difunctional or polyfunctional isocyanates. The isocyanates used for preparing the urethane prepolymers may be methylene diphenyl diisocyanate (MDI) and/or toluene diisocyanate (TDI). The curative in the composition may be a compound or mixture of compounds used to cross-link, therefore cure or harden, the urethane prepolymers.

Specifically, the curative reacts with isocyanates, causing the chains of the urethane prepolymers to link together to form the polyurethane. The curative may include 4,4′-methylene-bis(2-chloroaniline) (MBCA; also referred to by the tradename of MOCA®). In one embodiment, the composition includes 5 to 15 wt % of MBCA, 25 to 45 wt % of isocyanates, 45 to 55 wt % of polyols, and 1 to 5 wt % of conductive additive. The conductive additive is selected from at least one of carbon black, carbon fibers, and aluminum particles (i.e. the conductive additive is selected from a group comprising carbon black, carbon fibers, and aluminum particles). The conductive additive also may be other conductive nanoparticles such as carbon nanoparticles or carbon nanotubes. The aluminum particles may be aluminum sphere particles.

Preferably, the conductive additive has a conductivity of 1 to 30 millisiemens/centimeter (mS/cm) and a Zeta potential of −200 to 100 millivolt (mV). The isocyanates of the composition include TDI and MDI. The composition includes 25 to 35 wt % of TDI and 4 to 10 wt % of MDI. The polyols are poly(tetramethylene ether)glycol (PTMG). Further, prepolymers in the composition are often characterized by the weight percentage of unreacted isocyanate groups (NCO %) present in the prepolymer. In one embodiment, the composition has a NCO % within the range of 0.1 to 10 wt %.

Different weight percentage of the curative may result in different hardness of the resulting polyurethane polishing pad. In one embodiment, the composition includes 5 to 15 wt % of MBCA; and the polyurethane polishing pad has a hardness of around 60 Shore D. The composition for manufacturing the polyurethane polishing pad may further include other ingredients, such as surfactants, fillers, catalysts, processing aids, antioxidants, stabilizers, and/or lubricants.

Referring FIG. 2, a flowchart of a method of manufacturing a polyurethane polishing pad according to another implementation is illustrated. As shown in FIG.2, the method S200 includes actions S201, S202, and S203. In action S201, a composition for manufacturing the polyurethane polishing pad is provided. The composition can be referred to the previous embodiments. The composition may include 5 to 15 wt % of MBCA, 25 to 45 wt % of isocyanates, 45 to 55 wt % of polyols, and 1 to 5 wt % of conductive additive. The conductive additive of the composition is selected from at least one of carbon black, carbon fibers, and aluminum particles. In action S202, the composition is casted into an open mold.

For example, the open mold is a pan-type open mold. In action S203, the composition is heated to cure and produce a polyurethane resin foam. In one embodiment, the composition is heated to 90 to 150 degrees Celcius (° C.) for 5 to 10 hours for curing. The polyurethane resin foam is then sliced into polishing pads of desirable thickness.

In yet another embodiment, the present disclosure also provides a CMP apparatus for polishing a wafer. The CMP apparatus can be referred to the CMP apparatus 100 of FIG. 1. The CMP apparatus 100 includes a platen 110, a retaining ring 120, a carrier head 130, and a supply tube 151. The platen 110 has a polishing pad 111 for polishing the wafer S1 with a slurry 153. The retaining ring 120 is configured to hold the wafer S1. The carrier head 130 is connected to the retaining ring 120 and configured to rotate the retaining ring 120.

The supply tube 151 is configured to provide the slurry 153 to the polishing pad 111 of the platen 110. The CMP apparatus 100 further includes a drive motor 140 connected to the carrier head 130, and a filter assembly 154 connected to the supply tube 151. The drive motor 140 rotates the carrier head 130 in the direction 141, and optionally reciprocates transversely in the directions 142. The filter assembly 154 is configured to filter large particles (e.g., agglomerated particles) in the slurry 153 to prevent causing defects on the surface of the wafer S1.

The polishing pad 111 of the platen 110 is a polyurethane polishing pad manufactured from a composition. The composition can be referred to the previous embodiments. The composition includes 5 to 15 wt % of MBCA, 25 to 45 wt % of isocyanates, 45 to 55 wt % of polyols, and 1 to 5 wt % of conductive additive. The conductive additive of the composition is selected from at least one of carbon black, carbon fibers, and aluminum particles. The details of the composition and the manufacturing method can be referred to previous implementations without further description herein.

As described above, the polyurethane polishing pad of the implementations of the present disclosure is manufactured from a composition having urethane prepolymers and conductive additives. The conductive material in the polishing pad allows the pad surface to be conductive and remove the electrostatic charges accumulated on the wafer surface.

Therefore, circuit shortage and/or defects of the wafer caused by the electrostatic charges can be reduced.

The implementations shown and described above are only examples. Many details are often found in the art such as the other features of a polyurethane polishing pad and a composition for manufacturing the same. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the implementations described above may be modified within the scope of the claims.

What is claimed is:

1. A polyurethane polishing pad manufactured from a composition, the composition comprising:
5 to 15 weight percent (wt %) of 4,4′-methylene-bis(2-chloroaniline) (MBCA);
25 to 45 wt % of isocyanates;
45 to 55 wt % of polyols; and
1 to 5 wt % of conductive additive, wherein the conductive additive is selected from at least one of carbon black, carbon fibers, and aluminum particles.

2. The polishing pad of claim 1, wherein the conductive additive of the composition has a conductivity within a range of 1 to 30 mS/cm.

3. The polishing pad of claim 1, wherein the conductive additive of the composition has a Zeta potential within a range of −200 to 100 mV.

4. The polishing pad of claim 1, wherein the isocyanates of the composition comprise toluene diisocyanate (TDI) and methylene diphenyl diisocyanate (MDI), and the composition comprises 25 to 35 wt % of TDI and 4 to 10 wt % of MDI.

5. The polishing pad of claim 1, wherein the polyols are poly(tetramethylene ether)glycol (PTMG).

6. The polishing pad of claim 1, wherein the composition further comprises a weight percentage of unreacted isocyanate groups (NCO %) within a range of 0.1 to 10 wt %.

7. A method of manufacturing a polyurethane polishing pad, the method comprising:
providing a composition for manufacturing the polishing pad, wherein the composition comprises:
5 to 15 wt % of MBCA;
25 to 45 wt % of isocyanates;
45 to 55 wt % of polyols; and
1 to 5 wt % of conductive additive, wherein the conductive additive is selected from at least one of carbon black, carbon fibers, and aluminum particles;
casting the composition into an open mold; and
heating the composition to cure the composition and produce a polyurethane resin foam.

8. The method of claim 7, wherein the conductive additive of the composition has a conductivity with a range of 1 to 30 mS/cm.

9. The method of claim 7, wherein the conductive additive of the composition has a Zeta potential within a range of −200 to 100 mV.

10. The method of claim 7, wherein the isocyanates of the composition comprise TDI and MDI, and the composition comprises 25 to 35 wt % of TDI and 4 to 10 wt % of MDI.

11. The method of claim 7, wherein the polyols of the composition are PTMG.

12. The method of claim 7, wherein the composition has a NCO % within a range of 0.1 to 10 wt %.

13. The method of claim 7, wherein the composition is heated to a temperature within a range of 90 to 150 degrees Celcius for curing.

14. A CMP apparatus for polishing a wafer, the CMP apparatus comprising:
a platen having a polishing pad for polishing the wafer with a slurry, wherein the polishing pad is a polyurethane polishing pad manufactured from a composition comprising:
15 to 15 wt % of MBCA;
25 to 45 wt % of isocyanates;
45 to 55 wt % of polyols; and
1 to 5 wt % of conductive additive, wherein the conductive additive is selected from at least one of carbon black, carbon fibers, and aluminum particles;
a retaining ring configured to hold the wafer, and a carrier head connected to the retaining ring and configured to rotate the retaining ring.
